(19) United States
(12) Patent Application Publication
(10) Pub. No.: US 2010/0309943 A1
(43) Pub. Date: Dec. 9, 2010

(54) LONG WAVELENGTH NONPOLAR AND SEMIPOLAR (Al,Ga,In)N BASED LASER DIODES

(75) Inventors: Arpan Chakraborty, Goleta, CA (US); You-Da Lin, Goleta, CA (US); Shuji Nakamura, Santa Barbara, CA (US); Steven P. DenBaars, Goleta, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 12/795,360

(22) Filed: Jun. 7, 2010

Related U.S. Application Data
(60) Provisional application No. 61/184,729, filed on Jun. 5, 2009.

(51) Int. Cl. H01S 5/00; H01L 21/20

(52) U.S. Cl. 372/45.012; 438/47; 438/31; 257/E21.09

(57) ABSTRACT

A laser diode, grown on a miscut nonpolar or semipolar substrate, with lower threshold current density and longer stimulated emission wavelength, compared to conventional laser diode structures, wherein the laser diode's (1) n-type layers are grown in a nitrogen carrier gas, (2) quantum well layers and barrier layers are grown at a slower growth rate as compared to other device layers (enabling growth of the p-type layers at higher temperature), (3) high Al content electron blocking layer enables growth of layers above the active region at a higher temperature, and (4) asymmetric AlGaN SPSLS allowed growth of high Al containing p-AlGaN layers. Various other techniques were used to improve the conductivity of the p-type layers and minimize the contact resistance of the contact layer.

### CROSS-REFERENCE TO RELATED APPLICATIONS

This application claims the benefit under 35 U.S.C. Section 119(e) of co-pending and commonly assigned U.S. Provisional Patent Application Ser. No. 61/184,729, filed on Jun. 5, 2009, by Arpan Chakraborty, You-Da Lin, Shuji Nakamura, and Steven P. DenBaars, entitled “LONG WAVELENGTH m-PLANE (Al,Ga,In)N BASED LASER DIODES” attorney's docket number 30794.315-US-P1 (2009-616-1);

which application is incorporated by reference herein.

This application is related to the following co-pending and commonly-assigned U.S. Patent Applications:

Utility application Ser. No. 12/716,176, filed on Mar. 2, 2010, by Robert M. Farrell, Michael Iza, James S. Speck, Steven P. DenBaars, and Shuji Nakamura, entitled “METHOD OF IMPROVING SURFACE MORPHOLOGY OF (Ga,Al,In,B)N THIN FILMS AND DEVICES GROWN ON NONPOLAR OR SEMIPOLAR (Ga,Al,In,B)N SUBSTRATES,” attorneys' docket number 30794.306-US-U1 (2009-429-1), which application claims the benefit under 35 U.S.C. Section 119(e) of U.S. Provisional Patent Application Ser. No. 61/156,710, filed on Mar. 2, 2009, by Robert M. Farrell, Michael Iza, James S. Speck, Steven P. DenBaars, and Shuji Nakamura, entitled “METHOD OF IMPROVING SURFACE MORPHOLOGY OF (Ga,Al,In,B)N THIN FILMS AND DEVICES GROWN ON NONPOLAR OR SEMIPOLAR (Ga,Al,In,B)N SUBSTRATES,” attorney's docket number 30794.306-US-P1 (2009-429-1); and U.S. Provisional Patent Application Ser. No. 61/184,535, filed on Jun. 5, 2009, by Robert M. Farrell, Michael Iza, James S. Speck, Steven P. DenBaars, and Shuji Nakamura, entitled “METHOD OF IMPROVING SURFACE MORPHOLOGY OF (Ga,Al,In,B)N THIN FILMS AND DEVICES GROWN ON NONPOLAR OR SEMIPOLAR (Ga,Al,In,B)N SUBSTRATES,” attorney's docket number 30794.306-US-P2 (2009-429-2);

PCT international patent application Ser. No. ______, filed on same date herewith, by Arpan Chakraborty, You-Da Lin, Shuji Nakamura, and Steven P. DenBaars, entitled “ASYMMETRICALLY CLADDED LASER DIODE,” attorneys' docket number 30794.314-US-WO (2009-614-2), which application claims the benefit under 35 U.S.C. Section 119(e) of U.S. Provisional Application Ser. No. 61/184,668, filed Jun. 5, 2009, by Arpan Chakraborty, You-Da Lin, Shuji Nakamura, and Steven P. DenBaars, entitled “ASYMMETRICALLY CLADDED LASER DIODE,” attorneys' docket number 30794.314-US-P1 (2009-614-1);

which applications are incorporated by reference herein.

### STATEMENT REGARDING FEDERALLY SPONSORED RESEARCH AND DEVELOPMENT

This invention was made with Government support under Grant No. FA8718-08-0005 awarded by DARPA-VIGIL. The Government has certain rights in this invention.

### BACKGROUND OF THE INVENTION

1. Field of the Invention

This invention relates to laser diodes (LDs), in particular, the development high-efficiency nonpolar and semipolar LDs emitting at long wavelengths, for example, in the blue-green spectral range.

2. Description of the Related Art

Since the first demonstration of the violet LD based on the c-plane of wurtzite (Al, In, Ga)N material [1], c-plane technology has been commercially applied to violet, blue, and blue-green LDs. Recently, nonpolar m-plane GaN-based violet LDs were reported [2-3] and LD technology based on the m-plane has progressed rapidly. Due to the nature of nonpolar planes, the absence of spontaneous and piezoelectric polarization-related electric fields along the growth direction can realize perfect overlap of electron and hole wave functions in a InGaN multi quantum well (MQW) as well as a high radiative recombination rate, especially in a high indium composition quantum well (emitting in the blue and green spectral regions) [4]. For LDs, higher gain for nonpolar and semipolar orientations due to a negligible quantum confined stark effect (QCSE), and anisotropic band structures, was theoretically predicted by Park et al [5-6]. Actually, lower blue shift before lasing and higher slope efficiency than c-plane LDs were confirmed in actual LD operation [7-10]. LDs emitting beyond the blue spectral region have also been reported based on c-plane technology, but the slope efficiency was low due to QCSE-related low internal efficiency and high mirror reflectivities [11-12]. Hence, to achieve high power blue, blue-green, and green light emitting LDs, nonpolar nitrides are considered an ideal material [2, 3, 7-9, 13-15].

Miscut (or off-axis) substrates are widely used in other material systems to improve material quality and laser performance. To date, very few groups have reported device results based on miscut m-plane GaN substrates. Hirai et al. [16] and Farrell et al. [17] reported the observation of pyramidal hillocks on Si-doped GaN and LED structures grown on nominal on-axis m-plane GaN substrates. Farrell et al. [17] reported that the number of pyramidal hillocks can be effectively reduced by using vicinal substrates. Smoother surfaces of LED structures grown on off-angle substrates were also reported by Yamada et al. [18] However, all the m-plane GaN LDs reported so far were grown on nominally on-axis m-plane substrates [2-3, 7-9, 13-15].

Thus, conventional state-of-the-art nonpolar GaN based LDs are grown on nominally on-axis m-plane GaN substrates, [7, 9, 13, 19]. In addition:

(a) the n-type GaN contact layer and n-type AlGaN cladding layers in conventional state-of-the-art m-plane GaN based LDs are grown using hydrogen as carrier gas, [7, 9, 13, 19];

(b) conventional state-of-the-art m-plane GaN based LDs do not use high Indium (In) content InGaN separate confinement heterostructure (SCH) layers;

(c) conventional state-of-the-art m-plane GaN based LDs do not use an asymmetric AlGaN/GaN short period superlattice structure (SPSLS); and

(d) conventional state-of-the-art m-plane GaN based LDs do not use a Metal Organic Chemical Vapor Deposition (MOCVD) grown Mg—Ga—N contact layer to reduce contact resistance.

Consequently, there is a need in the art for improved LD structures. The present invention satisfies this need.

### SUMMARY OF THE INVENTION

To overcome the limitations in the prior art described above, and to overcome other limitations that will become apparent upon reading and understanding the present specification, the present invention describes techniques to fabricate long wavelength laser diodes (LDs) employing nonpolar and semipolar InGaN/GaN based active regions. The invention features novel structure and epitaxial growth techniques to improve structural, electrical and optical properties of long wavelength LDs, especially in the blue-green spectral range. Some of the key features include using miscut substrates and unconventional growth conditions in order to maintain smooth surface morphology, reduce waveguide scattering, and use of novel growth techniques to lower p-GaN contact resistance.

For example, the present invention discloses a method of fabricating a III-nitride laser diode (LD) structure, comprising growing one or more III-nitride device layers for a LD on an off-axis surface of an m-plane III-nitride substrate. The surface may be off-axis by −1 or +1 degree with respect to an m-plane of the substrate, and towards a c direction of the substrate. The surface may be off-axis by more than −1 or +1 degree with respect to an m-plane of the substrate, and towards a c direction of the substrate. These surfaces are more semipolar than nonpolar in nature.

The method may further comprise using 100% nitrogen carrier gas at atmospheric pressure to grow the one or more device layers on the off-axis surface of the substrate, resulting in the device layers having smooth surface morphology free of pyramidal hillocks observed in device layers grown on nominally on-axis m-plane GaN substrates. The device layers grown using the nitrogen carrier gas at atmospheric pressure may comprise all of the LD structure's n-type layers, including the silicon-doped n-type AlGaN/GaN superlattice, resulting in smooth interfaces and excellent structural properties for the LD structure, as compared to device layers grown without using 100% nitrogen carrier gas.

The method may further comprise growing one or more quantum wells at a first growth rate of more than 0.3 Angstroms per second and less than 0.7 Angstroms per second, and slower than a growth rate used for other layers in the LD structure.

The method may further comprise growing the quantum wells at a first temperature and with an Indium content so that the quantum wells emit green light, wherein the first growth rate maintains smooth interfaces and prevents faceting as compared to the quantum wells grown at a different growth rate.

Each of the quantum wells may be between quantum well barriers to form a light emitting active region, and the method may further comprise growing the quantum well barriers at a second growth rate slower than the first growth rate, resulting in smooth surface morphology and interfaces for the device layers, including the quantum wells, grown on the quantum well barriers, as compared to the barriers grown at a different faster growth rate, for example.

The method may further comprise growing a high Aluminum content AlGaN electron blocking layer on the active region; and growing subsequent layers on the active region at a second temperature that is higher than the first temperature and as compared to without the high Al content AlGaN electron blocking layer.

High Indium content InₓGa₁₋ₓN separate confinement heterostructure (SCH) layers may be on either side of the active region and the electron blocking layer, with x>7%, and the method may further comprising growing the SCH layers at (1) a third temperature higher temperature than a temperature used to grow other layers in the LD structure, (2) a slower growth rate of more than 0.3 Angstroms per second and less than 0.7 Angstroms per second, and (3) a high Trimethylindium/Triethylgallium (TEG) ratio of greater than 1.1, resulting in a smooth and defect free wave-guiding layer.

The method may further comprise forming an AlGaN/GaN asymmetric superlattice as cladding layers, on either side of the active region, including alternating AlGaN and GaN layers with the AlGaN layer that is thicker than the GaN layer.

The method may further comprise forming and doping p-waveguide and p-cladding layers, on one side of the active region, with a magnesium concentration in a range 1×10¹⁸-2×10¹⁹ cm^{˜3}.

The method may further comprise depositing a p-GaN contact layer on a p-cladding layer, with a thickness less than 15 nm and a magnesium doping between 7×10¹⁹-3×10²⁰.

Following the depositing of the p-GaN contact layer, the method may further comprise cooling the LD structure down in nitrogen and ammonia ambient, and flowing a small amount of Bis(cyclopentadienyl)magnesium (Cp₂Mg) until a temperature drops below 700 degrees Celsius, thereby forming a Mg—Ga—N layer that has a lower contact resistance to the LD structure.

Thus, the present invention further discloses a III-nitride device layer in a III-nitride based laser diode (LD) structure, comprising a III-nitride device layer for a LD grown on an off-axis surface of an m-plane III-nitride substrate. The III-nitride device layer may have a top surface with a root mean square (RMS) surface roughness across an area of 25 μm² of 1 nm or less, and/or be free of pyramidal hillocks, and/or be smoother than a top surface of the III-nitride device layer grown on a nominally on-axis m-plane substrate, and/or smoother than the surface shown in FIG. 4(a).

A plurality of the device layers may be such that the top surface is an interface between two of the device layers grown one on top of another; and the interface is between one or more of the following: a quantum well and a quantum well barrier, between a waveguide layer and a cladding layer, or between a waveguide layer and a light emitting active layer.

The device layers may be in the LD structure processed into the LD, such that, with facet coating, the LD has a threshold current density of 18 kA/cm² or less.

The device layer may be a light emitting active layer including an InGaN quantum well layer having higher In composition, with less In fluctuation across the InGaN quantum well layer, as compared to In composition and In fluctuation in the light emitting InGaN quantum well grown on an on-axis m-plane substrate, or as compared to In composition and In fluctuation shown in FIG. 5(a)).

The device layer may be an Mg—Ga—N contact layer having a thickness less than 15 nm. A contact resistance to the Mg—Ga—N contact layer may be less than 4E-4 Ohm-cm².

When the LD structure is processed into an LD, the LD may emit light having peak intensity at a wavelength corresponding to at least blue-green or green light.

### BRIEF DESCRIPTION OF THE DRAWINGS

Referring now to the drawings in which like reference numbers represent corresponding parts throughout:

FIG. 1(a) is a schematic cross-section of a LD structure, FIG. 1(b) is a schematic cross-section of a quantum well structure, FIG. 1(c) is a schematic cross-section of a first embodiment of a (20-21) LD device structure, and FIG. 1(d) is a schematic cross-section of a second embodiment of a (20-21) LD device structure.

FIG. 2(a) shows an X-ray Diffraction (XRD) scan of an n-type AlGaN/GaN superlattice grown using nitrogen carrier gas, and FIG. 2(b) shows an XRD scan of an n-type AlGaN/GaN superlattice grown using hydrogen carrier gas, plotting counts per second (counts/s) vs. 2Theta, wherein k represents 1000 counts and M represents 1 million counts (e.g., 100k is 100000 and 1 M is 1000000).

FIG. 3(a) plots an L-I (light output-current) characteristic of a LD structure (such as the structure shown in FIG. 1(a)) on a −1 degree (deg) miscut (towards the c direction of an) m-plane substrate, plotting intensity emitted (arbitrary units) as a function of wavelength (nanometers, nm) of the light, wherein the device has a threshold current Iₜₕ=652 milliamps (mA) (current density Jₜₕ=43 kA/cm²), a peak emission wavelength of 478.6 nm, and the different curves (from top to bottom) are for a forward drive current I_{f} greater than Iₜₕ (>Iₜₕ), less than Iₜₕ (<Iₜₕ), 400 mA, and 100 mA.

FIG. 3(b) plots the power in milliwatts (mW) of light emitted from, and forward Voltage V_{f} (V) across, a LD structure on a −1 deg miscut (towards the c direction of an) m-plane GaN substrate (e.g., comprising the structure shown in FIG. 1(a) and measured in FIG. 3(a)), as a function of forward drive current I_{f} (mA), wherein the device has Iₜₕ=520 mA (Jₜₕ=34 kA/cm²) and the different curves A, B, C, D and E are for different devices from one sample, thereby showing the performance distribution and yield.

FIG. 3(c) plots the L-I characteristic of a LD structure on a nominally on-axis m-plane GaN substrate, plotting intensity emitted (arbitrary units) as a function of wavelength (nm) of the light, wherein the device has a threshold current Iₜₕ=684 mA (current density Jₜₕ=45.6 kA/cm²), a peak emission wavelength of 471.9 nm, and the different curves (from top to bottom) are for a forward drive current I_{f} greater than Iₜₕ (>Iₜₕ), less than Iₜₕ (<Iₜₕ), 500 mA, 300 mA, and 100 mA.

FIG. 3(d) plots the power (mW) of light emitted from, and V_{f} (V) across, a LD structure on a nominally on-axis m-plane substrate (e.g. a device as shown and measured in FIG. 3(c)), as a function of forward drive current I_{f}, wherein the structure has a 2 μm ridge, Iₜₕ=684 mA, and Jₜₕ=45.6 kA/cm², and the different curves A, B are for different devices from one sample, thereby showing the performance distribution and yield.

FIG. 3(e) plots current density Jₜₕ (kA/cm²) as a function of LD cavity length in micrometers (μm), and FIG. 3(f) plots lasing wavelength (nm) as a function of LD cavity length (μm), for (20-21) LDs, for a pulsed 0.01% duty cycle.

FIG. 3(g) is an image of a semipolar (20-21) green LD emitting 516 nm light showing cleaved facets and FIG. 3(h) is an image of a semipolar (20-21) green LD emitting green light.

FIG. 3(i) plots intensity of emission in arbitrary units (a.u.) as function of wavelength in nm for a semipolar (20-21) green LD.

FIG. 3(j) plots output power in milliwatts (mW) as function of drive current in milliamps (mA), and voltage as a function of the drive current (IV curve), for a semipolar (20-21) green LD (L-I-V curve).

FIG. 3(k) plots electroluminescence intensity (EL) in a.u. (arb. Unit) as a function of emission wavelength, for different drive currents (from top to bottom curve, 1100 mA, 1000 mA, 800 mA, 600 mA, 400 mA, 200 mA, 100 mA, 50 mA, 20 mA, 10 mA, and 5 mA), for a semipolar (30-31) GaN LD.

FIG. 3(l) plots peak light emission wavelength (nm) as a function of current density (kA/cm²), and light emission Full Width at Half Maximum (FWHM) as a function of current density, wherein circles are data showing the (30-31) LD electroluminescence FWHM, dark squares are data showing the (30-31) LD EL wavelength (λ), and lighter squares are data showing a c-plane LD EL wavelength (λ), for a semipolar (30-31) GaN LD.

FIG. 3(m) plots output power (mW) and Voltage (V) as a function of current density (kA/cm²) and current (mA), for a semipolar (30-31) GaN LD, showing the IV curve, wherein the inset plots EL intensity (arbitrary units, arb. units) as a function of wavelength (nm) showing a peak wavelength of emission λ=447.7 nm, also for the semipolar (30-31) GaN LD.

FIG. 4(a) shows Nomarski optical microscopy images of a LD grown on a nominally on-axis m-plane GaN substrate (e.g., as measured in FIG. 3(c) and FIG. 3(d)), and FIG. 4(b) shows a Nomarski optical microscopy image of a LD grown on a 1 degree miscut [towards the (000-1) direction] m-plane GaN substrate (e.g., comprising the structure shown in FIG. 1(a) and measured in FIG. 3(a) and FIG. 3(b)), wherein the scale in FIG. 4(a) and FIG. 4(b) is 100 micrometers (μm) and is the same in both vertical and horizontal directions.

FIG. 5(a) shows a Fluorescence optical microscopy image of a LD grown on a nominally on-axis m-plane GaN substrate (e.g., as measured in FIG. 3(c) and FIG. 3(d)), and FIG. 5(b) shows a Fluorescence optical microscopy image of a LD grown on a 1 degree miscut [towards the (000-1) direction] m-plane GaN substrate (comprising the structure as shown in FIG. 1(a) and measured in FIGS. 3(a) and 3(b)), wherein the scale in FIG. 5(a) and FIG. 5(b) is 100 micrometers (μm) and the scale is the same in both horizontal and vertical directions.

FIG. 5(c) is a fluorescence microscope image of a LD grown on a (20-21) GaN substrate, wherein the scale is 100 μm.

FIG. 6 is a flowchart illustrating a method of fabricating an LD structure according to the present invention.

FIG. 7(a) is a cross sectional schematic of one or more device layers on an off-axis substrate, and FIG. 7(b) is a cross-sectional schematic of hillocks on a device layer surface grown on an on-axis m-plane substrate.

FIG. 8 is a p-contact matrix showing contact resistivity (ohm-cm²) as a function of Cp2Mg flow during cool down (sccm).

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Nomenclature

GaN and its ternary and quaternary compounds incorporating aluminum and indium (AlGaN, InGaN, AlInGaN) are commonly referred to using the terms (Al,Ga,In)N, III-nitride, Group III-nitride, nitride, Al_{(1-x-y)}In_{y}GaₓN where 0<x<1 and 0<y<1, or AlInGaN, as used herein. All these terms are intended to be equivalent and broadly construed to include respective nitrides of the single species, Al, Ga, and In, as well as binary, ternary and quaternary compositions of such Group III metal species. Accordingly, these terms comprehend the compounds AlN, GaN, and InN, as well as the ternary compounds AlGaN, GaInN, and AlInN, and the quaternary compound AlGaInN, as species included in such nomenclature. When two or more of the (Ga, Al, In) component species are present, all possible compositions, including stoichiometric proportions as well as “off-stoichiometric” proportions (with respect to the relative mole fractions present of each of the (Ga, Al, In) component species that are present in the composition), can be employed within the broad scope of the invention. Accordingly, it will be appreciated that the discussion of the invention hereinafter in primary reference to GaN materials is applicable to the formation of various other (Al, Ga, In)N material species. Further, (Al,Ga,In)N materials within the scope of the invention may further include minor quantities of dopants and/or other impurity or inclusional materials.

Moreover, throughout this disclosure, the prefixes n-, p-, and p⁺⁺-before the layer material denote that the layer material is n-type, p-type, or heavily p-type doped, respectively. For example, n-GaN indicates the GaN is n-type doped.

One approach to eliminating the spontaneous and piezoelectric polarization effects in GaN or III-nitride based optoelectronic devices is to grow the III-nitride devices on nonpolar planes of the crystal. Such planes contain equal numbers of Ga (or group III atoms) and N atoms and are charge-neutral. Furthermore, subsequent nonpolar layers are equivalent to one another so the bulk crystal will not be polarized along the growth direction. Two such families of symmetry-equivalent nonpolar planes in GaN are the {11-20} family, known collectively as a-planes, and the {1-100} family, known collectively as m-planes. Thus, nonpolar III-nitride is grown along a direction perpendicular to the (0001) c-axis of the III-nitride crystal.

Another approach to reducing polarization effects in (Ga,Al,In,B)N devices is to grow the devices on semipolar planes of the crystal. The term “semipolar plane” can be used to refer to any plane that cannot be classified as c-plane, a-plane, or m-plane. In crystallographic terms, a semipolar plane would be any plane that has at least two nonzero h, i, or k Miller indices and a nonzero 1 Miller index.

Technical Description

Device Structure

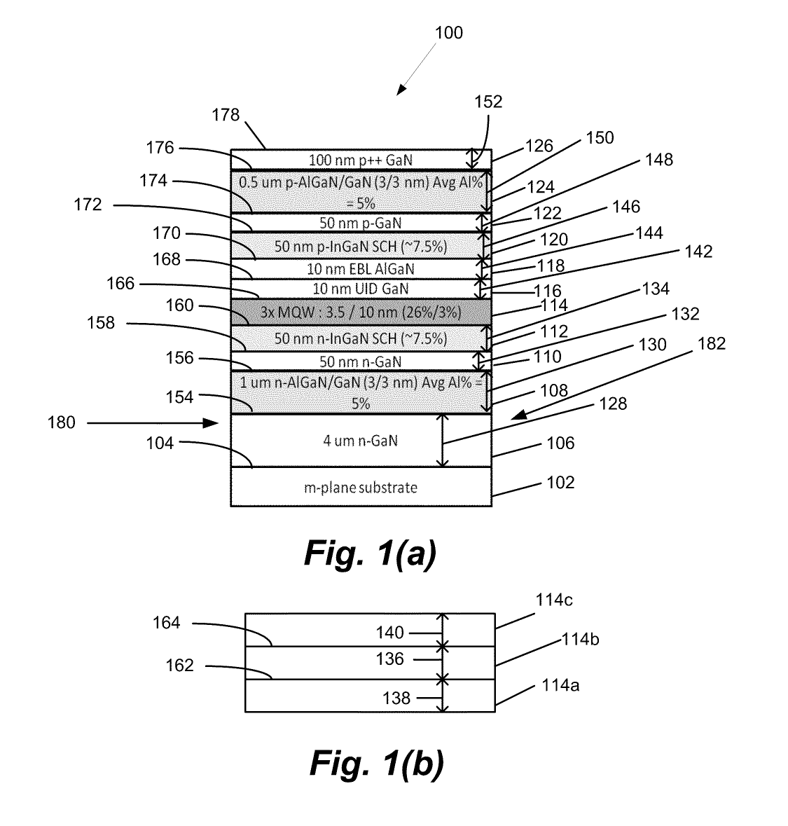

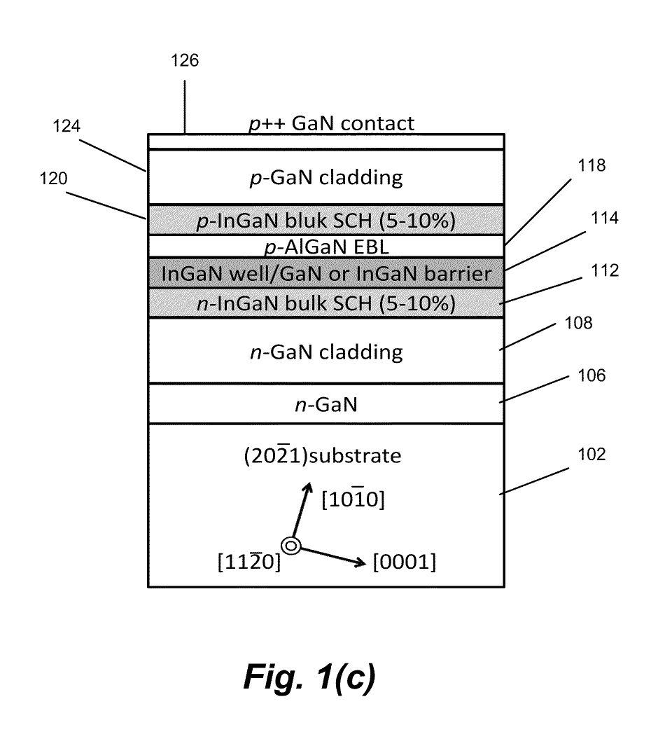

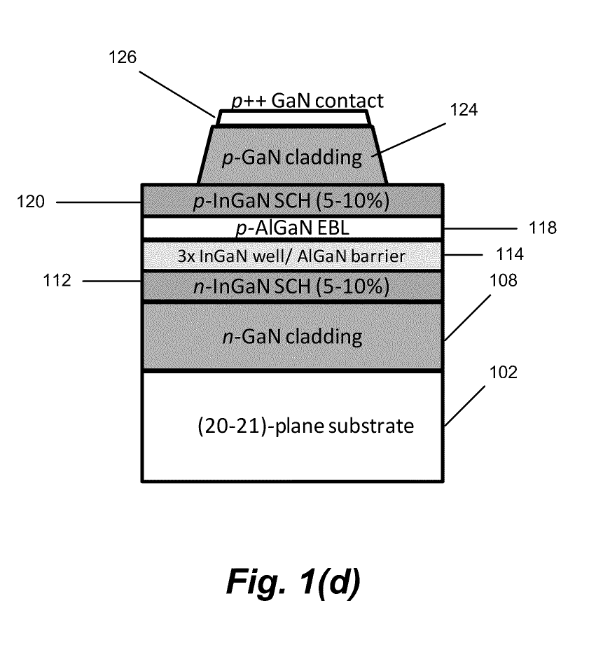

FIG. 1(a) is a cross sectional schematic of a LD structure grown according to the present invention, an optimized long wavelength m-plane LD design.

FIG. 1(a) and FIG. 1(b) illustrate a III-nitride laser diode (LD) structure 100, comprising a substrate 102 (e.g., an m-plane GaN substrate having an off-axis surface 104); an n-type GaN layer 106 deposited epitaxially on the off-axis surface 104 of the m-plane substrate 102; an n-type III-nitride cladding layer 108 (e.g., AlGaN/GaN) deposited epitaxially on the n-type layer 106; an n-GaN spacer layer 110 deposited epitaxially on the n-cladding layer 108; an n-type InGaN SCH layer 112 deposited epitaxially on the n-type GaN spacer layer 110; an active region 114 (comprising a first InGaN quantum well barrier layer 114a deposited epitaxially on the n-type InGaN SCH layer 112, an InGaN quantum well layer 114b deposited epitaxially on the first quantum well barrier layer 114a, a second InGaN quantum well barrier layer 114c deposited epitaxially on the InGaN quantum well layer 114b, wherein the InGaN quantum well layer 114b includes at least 20% Indium (In)); an unintentionally doped (UID) GaN layer 116 deposited epitaxially on the active region 114 (e.g., on second barrier layer 114c); an AlGaN electron blocking layer (EBL) 118 deposited epitaxially on the UID layer 116; a p-type InGaN SCH layer 120 deposited epitaxially on the EBL 118, wherein the n-type InGaN SCH layer 112 and the p-type InGaN SCH layer 120 both have an In composition greater than 7% (e.g., ˜7.5%); a p-GaN spacer layer 122 deposited epitaxially on the p-InGaN SCH 120; a p-type III-nitride (e.g., AlGaN/GaN) cladding layer 124 deposited epitaxially on the p-type GaN spacer layer 122; and a p-type GaN (p⁺⁺ GaN) contact layer 126 deposited epitaxially on the p-type III-nitride cladding layer 124.

In FIG. 1(a), the n-GaN layer 106 comprises a 4 μm thickness 128, the n-cladding layer 108 comprises a 1 μm thickness 130 (including alternating 3 nanometer (nm) thick AlGaN and 3 nm thick GaN layers for an average Aluminum (Al) content of 5%), the n-GaN spacer layer 110 comprises a 50 nm thickness 132, the n-InGaN SCH layer 112 comprises a 50 nm thickness 134, the active layer 114 comprises 3.5 nm thickness 136 InGaN quantum wells and 10 nm thickness 138, 140 InGaN quantum well barriers with 26% and 3% In composition respectively, the UID layer 116 comprises a 10 nm thickness 142, the EBL 118 comprises a 10 nm thickness 144, the p-InGaN SCH 120 comprises a 50 nm thickness 146, the p-GaN spacer 122 comprises a 50 nm thickness 148, the p-cladding 124 comprises a 0.5 μm thickness 150 (including alternating 3 nm thick AlGaN layers and 3 nm thick GaN layers for an average Al composition of 5%), and the p⁺⁺ GaN layer 126 comprises a 100 nm thickness 152 (however the p⁺⁺ GaN contact layer 126 preferably has a thickness 152 less than 15 nm).

The LD structure depicted in FIG. 1(a) further comprises (a) a first interface 154 between the n-type III-nitride cladding layer 108 and the n-type GaN layer 106, (b) a second interface 156 between the n-type cladding layer 108 and the n-type GaN spacer layer 110, (c) a third interface 158 between the n-GaN spacer layer 110 and the n-type InGaN SCH layer 112; (d) a fourth interface 160 between the first quantum well barrier layer 114a and the n-type InGaN SCH layer 112, (e) a fifth interface 162 between the InGaN quantum well layer 114b and the first quantum well barrier layer 114a, (f) a sixth interface 164 between the second quantum well barrier layer 114c and the InGaN quantum well layer 114b; (g) a seventh interface 166 between the UID GaN layer 116 and the second quantum well barrier 114c; (h) an eighth interface 168 between the UID layer 116 and the EBL 118; (i) an ninth interface 170 between the EBL 118 and the p-InGaN SCH 120; (j) a tenth interface 172 between the p-type InGaN SCH layer 120 and p-GaN spacer layer 122; (h) an eleventh interface 174 between the p-type III-nitride cladding layer 124 and the p-type GaN spacer 122; (i) a twelfth interface 176 between the p-type GaN contact layer 126 and the p-type III-nitride cladding layer 124; and (j) a top surface 178 of the p-type GaN contact layer 126.

FIG. 1(a) also illustrates facets 180, 182 that may be coated and act as mirrors for the LD cavity.

FIG. 1(c) illustrates another embodiment of the present invention, a LD epitaxial wafer device structure grown on a (20-21) substrate 102, comprising the n-GaN layer 106, n-GaN cladding layer 108, n-InGaN bulk SCH layer 112 with 5-10% In, active layer 114 comprising InGaN well with GaN or InGaN barrier, p-AlGaN EBL 118, p-InGaN bulk SCH layer 120 with 5-10% In, a p-GaN cladding 124, and p⁺⁺ GaN contact layer 126.

FIG. 1(d) illustrates yet another embodiment of the present invention comprising a semipolar (20-21) green light emitting (516 nm) LD device structure with InGaN waveguide and GaN cladding on a (20-21) substrate 102 (i.e., substrate wherein top surface 104 is a 20-21 plane), n-GaN cladding layer 108, n-InGaN SCH 112 with 5-10% In, active layer 114 comprising 3 InGaN wells with AlGaN barriers, p-AlGaN EBL 118, p-InGaN SCH layer 120 (with 5-10% In), p-GaN cladding layer 124, and p⁺⁺ GaN contact layer.

The goal of the present invention is to achieve smooth interfaces (e.g., 154-176) and surface (e.g, 178) morphology, together with a highly efficient active region 114, uniform and smooth guiding layers (e.g., 112, 120), low resistance cladding layers (e.g., 108, 124) with low refractive index, and low resistance contact layers (e.g, 126). For example:

1. The use of miscut (−1 degree towards c-direction) m-plane GaN substrates, along with template growth using 100% nitrogen carrier gas at atmospheric pressure resulted in smooth surface morphology, free of pyramidal hillocks commonly observed in conventional nominally on-axis m-plane GaN templates following metal organic chemical vapor deposition (MOCVD) regrowth.

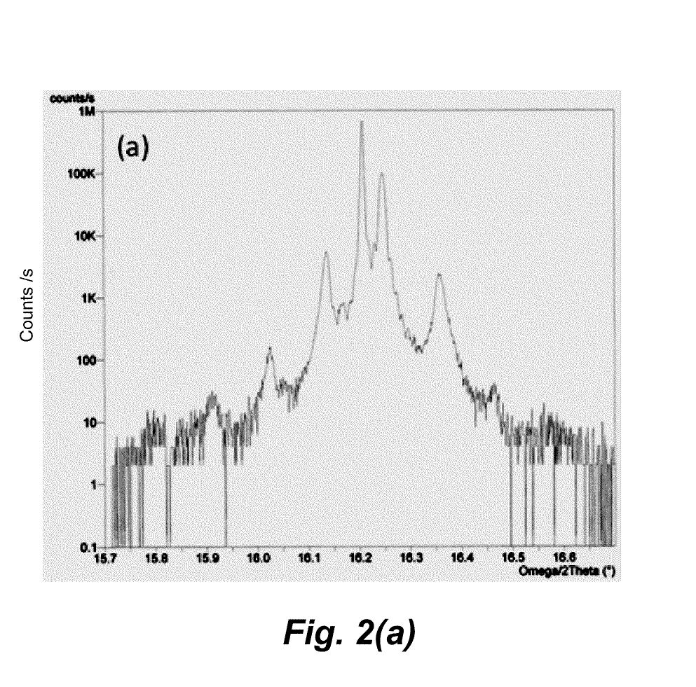

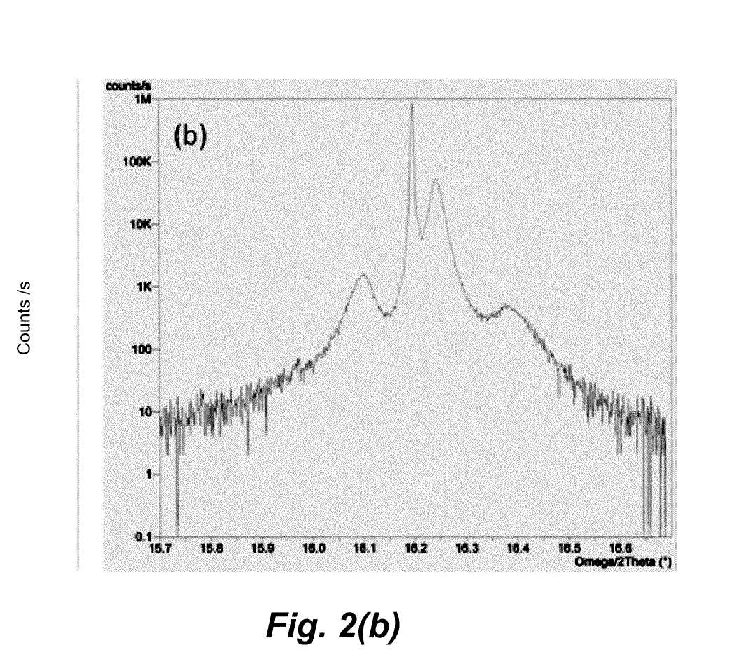

2. The use of 100% nitrogen carrier gas to grow a Si-doped n-type AlGaN/GaN superlattice (e.g., as used in n-cladding layer 108) resulted in smooth interfaces and excellent structural properties, as shown in FIG. 2(a). The superlattice in FIG. 2(a) has improved structural properties as compared to the superlattice shown in FIG. 2(b) (grown using a hydrogen carrier gas). FIG. 2(a) shows an III-nitride cladding device layer comprising asymmetric AlGaN/GaN SPSLS where the AlGaN layer is thicker than the GaN layer in the superlattice, and the superlattice structure has interfaces that are smoother with increased structural quality as compared to the structural quality shown in FIG. 2(b).

3. All layers except the p-InGaN SCH (e.g. 120), the p-GaN (e.g., 122) or p-AlGaN cladding (e.g., 124) and p-GaN contact layers (e.g., 126), were grown using 100% nitrogen carrier gas.

4. The use of high In-content InₓGa₁₋ₓN SCHs (x>7%) (e.g., 112, 120), grown at relatively high temperatures (as compared to the active region growth temperature), with slow growth rates (<0.7 Angstroms per second (Å/s)), and high Trimethylindium/Triethylgallium (TMI/TEG) ratio (>1.1), resulted in a smooth and defect free wave-guiding layer. However the growth rate is kept higher than 0.3 Å/s because lower growth rate results in lower In incorporation at the same growth temperature. Therefore, the growth rate of the InGaN SCH (0.3 Å/s<growth rate<0.7 Å/s) was optimized such that the InGaN layer was smooth and was grown at the highest possible temperature for better structural and electrical characteristics.

5. The quantum wells (e.g., 114b) were grown at a relatively slower growth rate (<0.7 Å/s) to maintain smooth interfaces (e.g, 162, 164) and prevent facetting at the lower growth temperatures needed for a green light emitting active region. Therefore, the growth rate of the InGaN wells (0.3 Å/s<growth rate<0.7 Å/s) was optimized such that the quantum well (QW) interfaces were smooth and the QW was grown at the highest possible temperature for the required emission wavelength, for better structural and optical characteristics. The TMI/TEG ratio during the growth of the wells was adjusted so that it was not in the In saturation regime for the set temperature.

6. The barriers (e.g., 114a, 114c) were grown at much slower growth rates compared to the well 114b (<0.3 Å/s), resulting in smooth surface morphology for the subsequent well-growth. The slower well and barrier growth rates resulted in smooth interfaces and flat interfaces (e.g. 162, 164, 166).

7. Asymmetric AlGaN/GaN SPSLS (e.g., 108, 124) were used to increase Aluminum (Al) content in the AlGaN cladding and prevent pre-reaction, especially during the growth of p-type AlGaN using hydrogen carrier gas. Al composition in AlGaN does not scale linearly with the TMA/TMG flow, due to pre-reactions. The asymmetric superlattice involved a thicker AlGaN layer and a thinner GaN layer, resulting in the same average Al composition as a symmetric superlattice structure with higher AlGaN composition in the AlGaN layer.

8. The AlGaN electron blocking layer (e.g., 118) is grown during a temperature ramp, using TEG as the gallium source.

9. The Magnesium (Mg) doping concentration in the p-waveguide (e.g., 120) and p-cladding layers (e.g., 124) is in the range 1E18-2E19 cm^{˜3}.

10. A thin 10 nm p-GaN contact layer (e.g., 126) with Mg doping between 7E19-3E20 cm^{˜3} was used instead of a thick contact layer (which is typically >15 nm).

11. Following the growth of the p-GaN contact layer, the sample was cooled down in nitrogen and ammonia ambient, and a small amount of Bis(cyclopentadienyl) Magnesium (Cp₂Mg) was flowed until a temperature of 700 degrees Celsius (° C.) was achieved. This resulted in the formation of an Mg—Ga—N layer (e.g., 126), that resulted in lower contact resistance.

This invention employed AlGaN cladding layers 108, 124, where typical Al composition can range from 2-10%. For typical LD structures, the number of active layer MQW periods can range from 2 to 6, the well width 136 can range from 1 to 8 nm, and the barrier width 138, 140 from 6 to 15 nm. Typical thickness 140 for the last barrier (e.g, 114c) is 5 to 20 nm. The last barrier is followed by an AlGaN EBL 118, for which the typical thickness 144 and Al concentration range from 6-20 nm and 10-30%, respectively. The AlGaN EBL 118 is typically doped with Mg.

The best way of practicing this invention would be to use it along with a nonpolar AlGaN clad-free structure (see e.g., U.S. Utility application Ser. No. ______, filed on same date herewith, by Arpan Chakraborty, You-Da Lin, Shuji Nakamura, and Steven P. DenBaars, entitled “ASYMMETRICALLY CLADDED LASER DIODE,” attorneys' docket number 30794.314-US-WO (2009-614-2), which application is incorporated herein), especially for blue-green spectral region light emission.

Device Performance

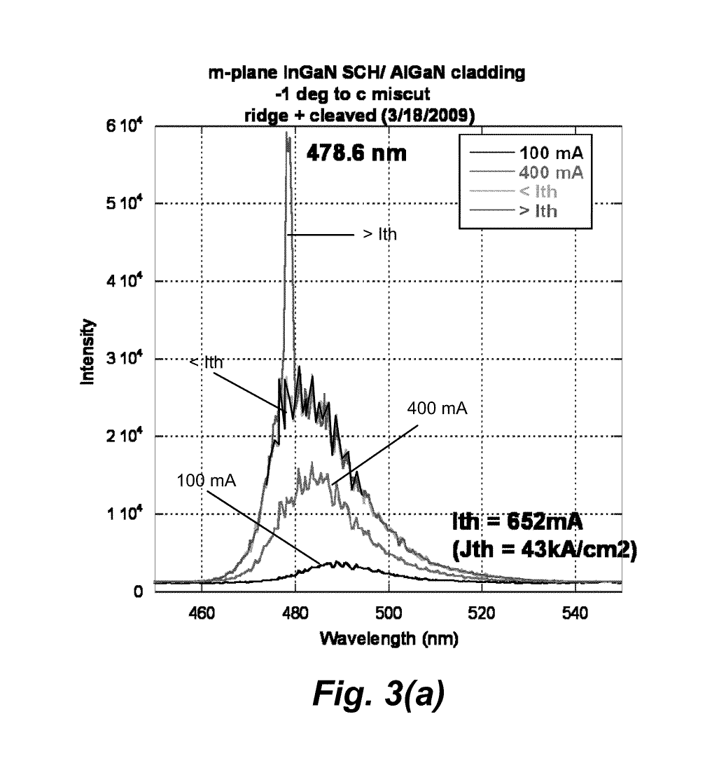

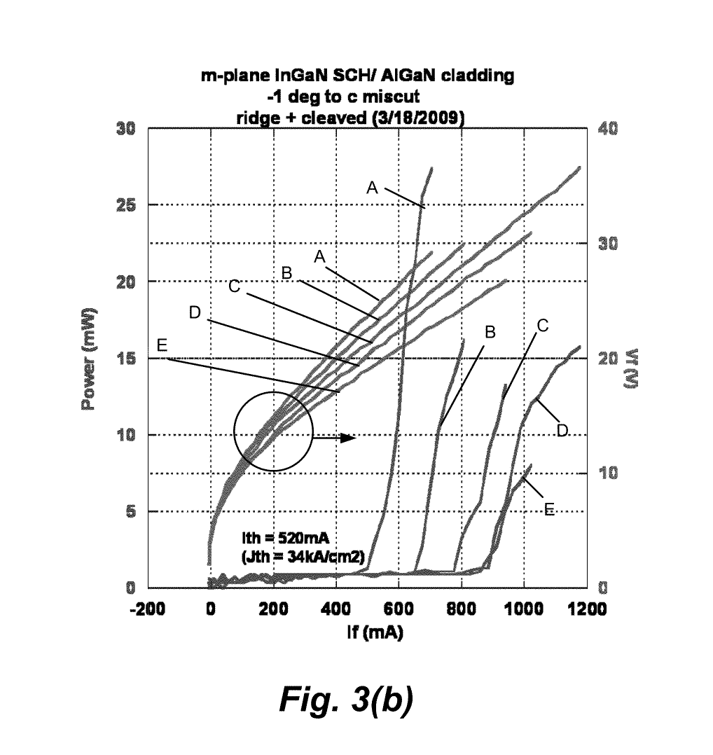

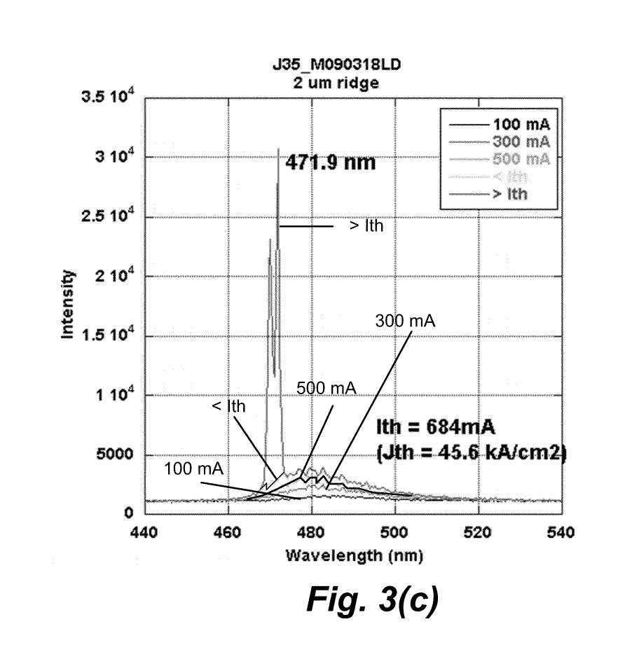

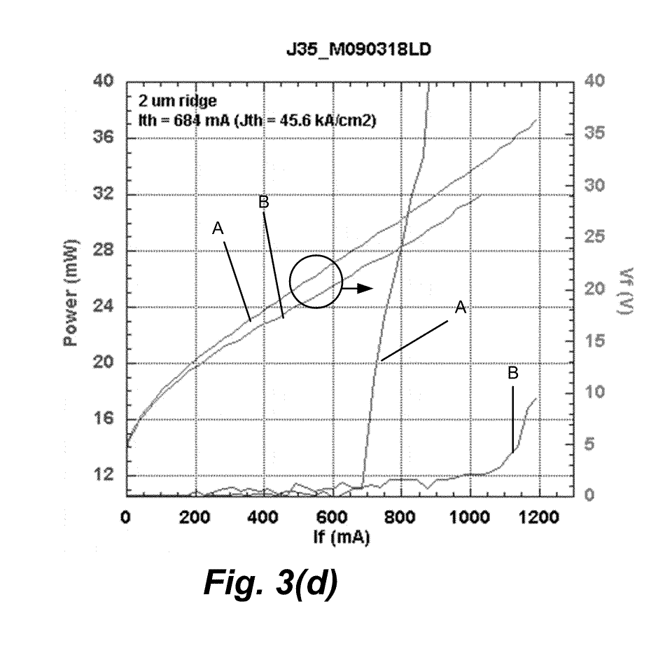

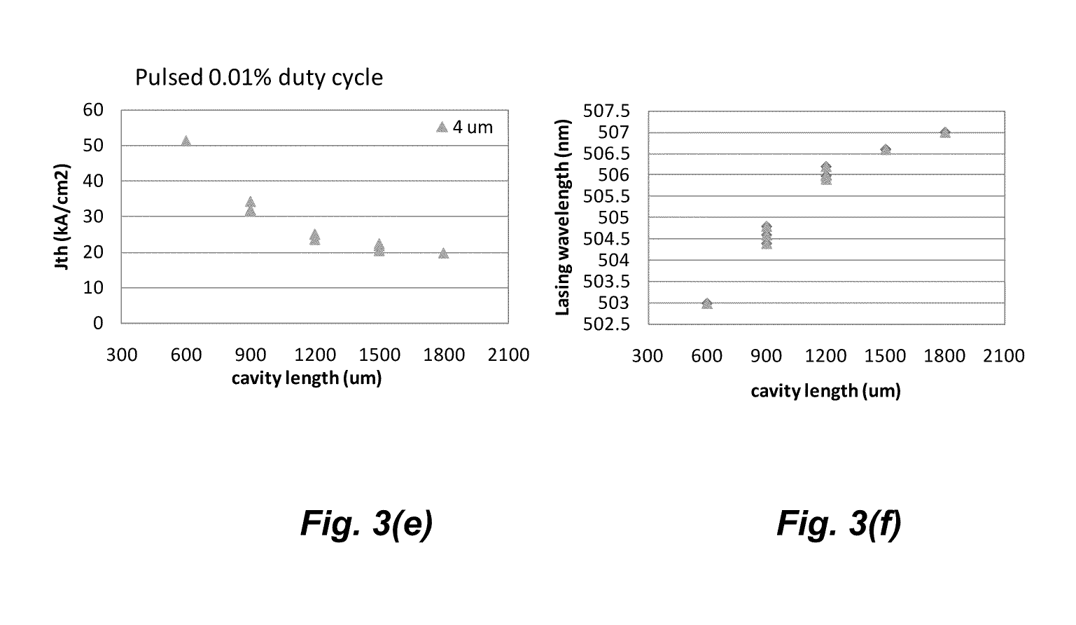

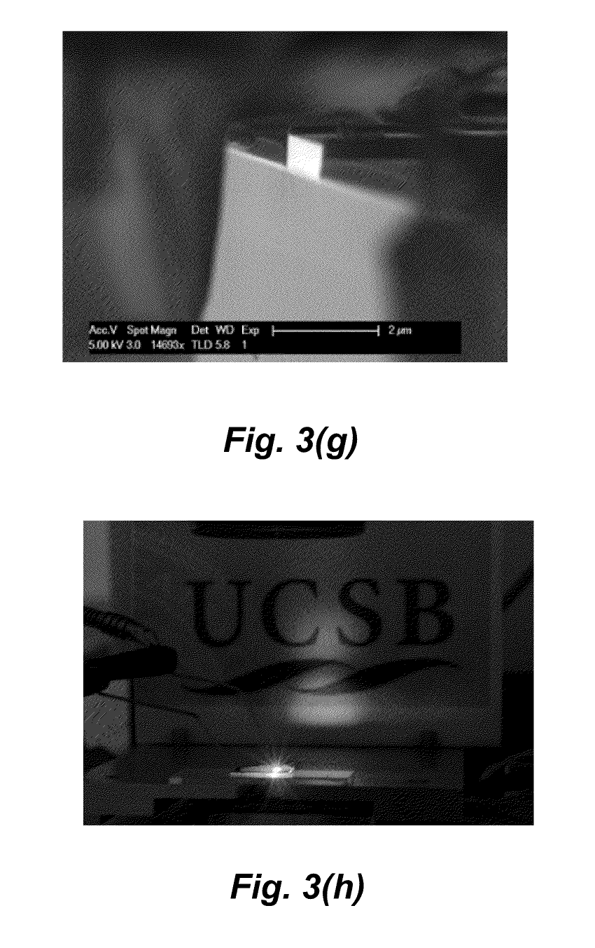

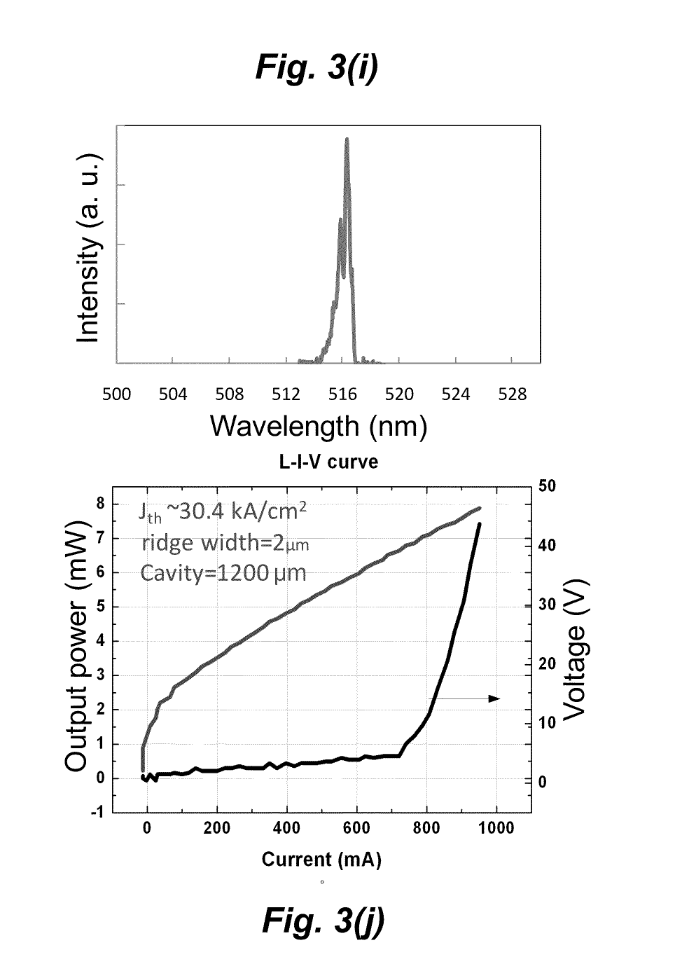

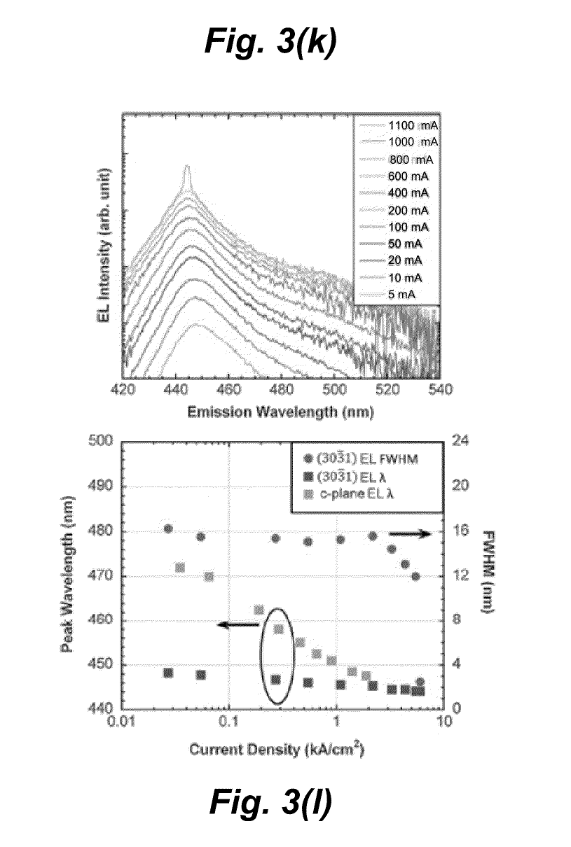

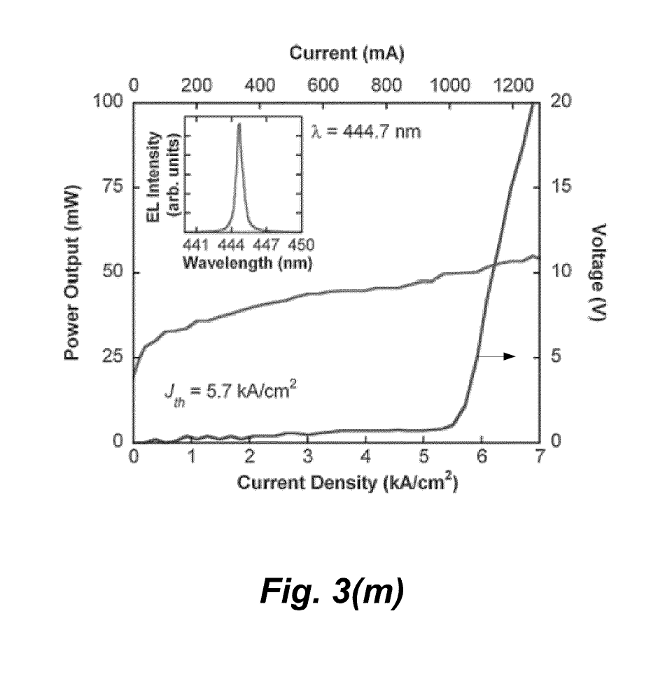

FIG. 3(a) illustrates an LD structure (e.g., as illustrated in FIG. 1(a)), wherein, when the LD structure is processed into an LD, the LD emits light having peak intensity at a wavelength in the blue-green spectral range (e.g., 440-520 nm). However, emission having peak intensity in the green spectral range is also possible.

FIG. 3(b) illustrates an LD structure (e.g., as illustrated in FIG. 1(a)), wherein, when the LD structure is processed into a LD, with facet 180, 182 coating, a threshold current density of 34 kA/cm² is achieved; however a threshold current density of 18 kA/cm² or less is also possible [20].

The devices measured in FIGS. 3(c), 3(d), 4(a) and 5(a) have the structure shown in FIG. 1(a) but grown on nominal on-axis m-plane substrates. Those devices were grown with nitrogen carrier gas for n-layer, high Indium (In) content InGaN SCH layers, an asymmetric AlGaN/GaN short period superlattice structure (SPSLS); and an MOCVD grown Mg—Ga—N contact layer to reduce contact resistance. However, they still have higher threshold current densities and shorter lasing wavelength because they were grown on nominal on-axis m-plane substrates. Growth technique and miscut substrates are both important.

Thus, the above techniques achieved a LD with much lower threshold current density (FIG. 3(b)) and longer stimulated emission wavelength (FIG. 3(a)), compared to a LD structure in FIG. 3(c) and FIG. 3(d).

FIG. 3(e) and FIG. 3(f) show (20-21) LD device performance, wherein long cavity can reduce mirror loss and results in low threshold current density (FIG. 3(e)), and low threshold current density results in longer lasing wavelength (FIG. 3(f)).

FIGS. 3(g) and 3(h) show LDs fabricated from the structure of FIG. 1(d), and FIG. 3(i) and FIG. 3(j) are measurements of the devices fabricated from the structure of FIG. 1(d), wherein FIG. 3(g) shows the cleaved facet of the LD device, and FIG. 3(h) shows the LD emitting green light under operation, FIG. 3(i) shows 516 nm wavelength emission of the LD, and FIG. 3(j) shows Jₜₕ˜30.4 kA/cm² for a ridge width of 2 μm, a cavity length of 1200 μm, and DBR facet coating of 97/99%.

FIG. 3(k)-(m) illustrate (30-31) GaN LD performance [20].

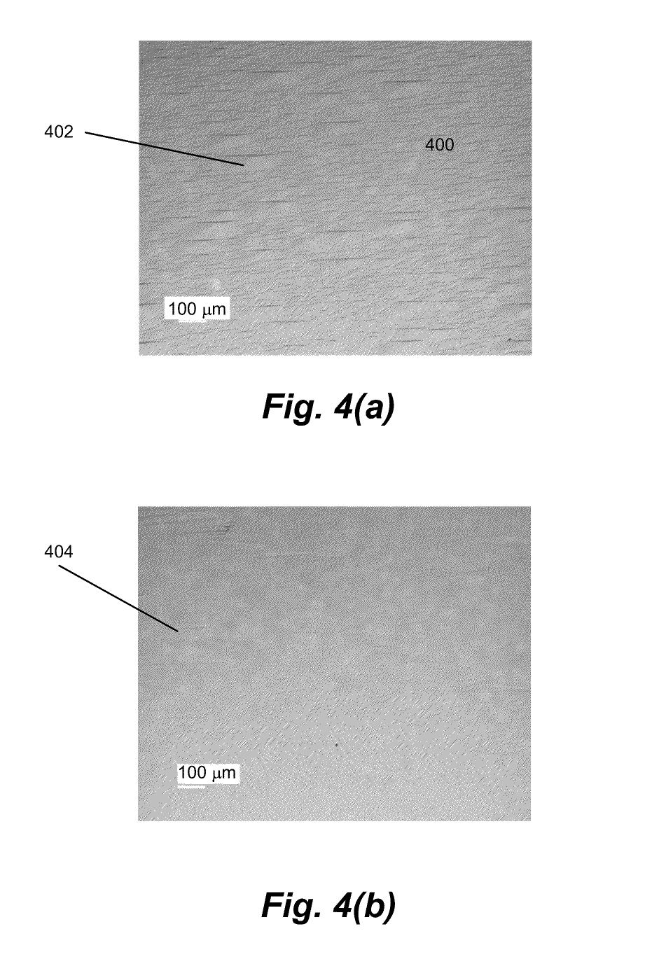

FIG. 4(a) shows the top surface 400 of an LD grown on a nominally on-axis m-plane substrate, showing pyramidal hillocks 402 (e.g. hillocks having pyramid shape (e.g., 4-sided pyramids wherein the sides are facets, or as described in U.S. Utility patent application Ser. No. 12/716,176, filed on Mar. 2, 2010, by Robert M. Farrell, Michael Iza, James S. Speck, Steven P. DenBaars, and Shuji Nakamura, entitled “METHOD OF IMPROVING SURFACE MORPHOLOGY OF (Ga,Al,In,B)N THIN FILMS AND DEVICES GROWN ON NONPOLAR OR SEMIPOLAR (Ga,Al,In,B)N SUBSTRATES,” attorney's docket number 30794.306-US-U1 (2009-429-1), for example).

FIG. 4(b) shows the techniques of the present invention achieved LD device layers with a pyramidal hillock-free and smoother surface morphology as compared to a device as shown, for example, in FIG. 4(a). For example, FIG. 4(b) illustrates the top surface 404 of a III-nitride device layer in a III-nitride based LD structure such as the structure in FIG. 1(a), wherein the III-nitride device layer 120 for the LD grown is on an (e.g., nominally) off-axis surface of an m-plane III-nitride substrate and the top surface 404 is free of pyramidal hillocks 402 and/or is smoother than a top surface 400 of the III-nitride device layer grown on an on-axis m-plane substrate (e.g., as shown in FIG. 4(a). FIG. 4(b) also shows the top surface 404 may be smoother than the top surface 400 of the III-nitride device layer grown with a hydrogen containing carrier gas or a carrier gas less than 100% nitrogen (as shown in FIG. 4(a)).

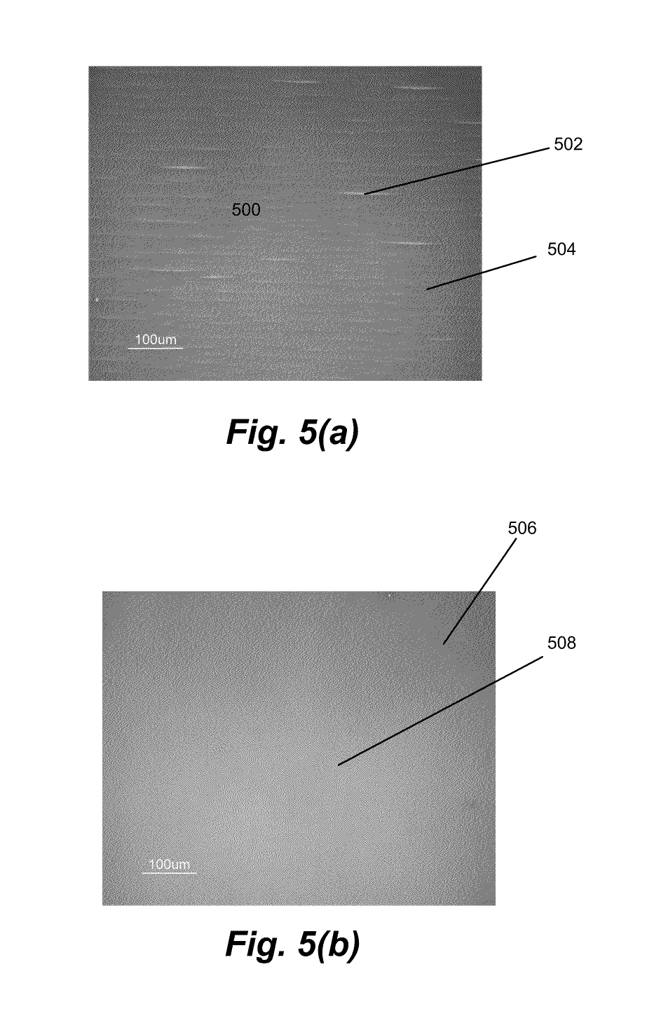

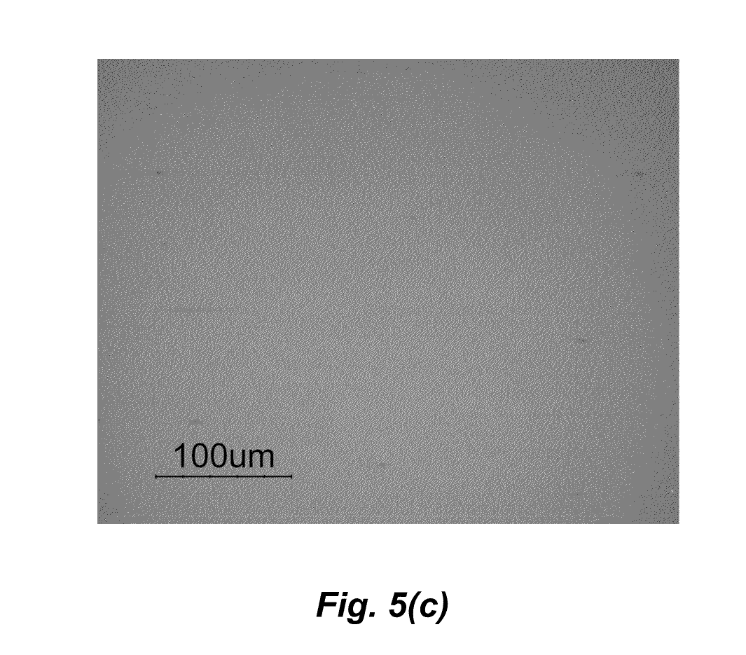

FIG. 5(a) shows a fluorescence optical microscopy image of a LD grown on a nominally on-axis m-plane substrate. The fluorescence originates from the active layer of the LD and is non-uniform (i.e., the fluorescence is brighter in some locations 502 across the surface 500 as compared to other locations 504).

FIG. 5(b) shows a fluorescence optical microscopy image of a LD having the structure e.g., as shown in FIG. 1(a), and grown on a 1 degree miscut [towards (000-1) direction] m-plane GaN substrate. FIG. 5(b) shows the present invention achieved higher In composition (with less In fluctuation) in the active region 114 as compared to an LD structure as shown, for example, in FIG. 5(a), because the distribution of fluorescence 508 is more uniform across the surface 506. FIG. 5(b) also shows the light emitting active quantum well device layer 114b has a higher In composition (with less In fluctuation) as compared to In composition and In fluctuation in the light emitting active layer grown on an on-axis m-plane substrate (e.g. as shown in FIG. 5(a)). The higher In composition is also evidenced by the brighter fluorescence over a larger area in FIG. 5(b) as compared to FIG. 5(a).

FIG. 5(c) is a fluorescence microscope image of an LD fabricated from the structure of FIG. 1(c).

While FIGS. 4(b) and 5(b) illustrate the top surface 404, 506 of the LD, in the case of a plurality of device layers, the present invention also enables the structure and properties illustrated in FIG. 4(b) and FIG. 5(b) for one or more of the interfaces 140-170 between two of the device layers grown one on top of another. For example, the interface 156, 158 between a quantum well 114b and a quantum well barrier 114a, 114c, the interface 150, 152 between a waveguide layer 112 and a cladding layer 108 or spacer layer 110, or the interface 154 between a waveguide layer 112 and a light emitting active layer 114, may have the structure and properties evidenced by FIGS. 4(b) and 5(b).

Process Steps

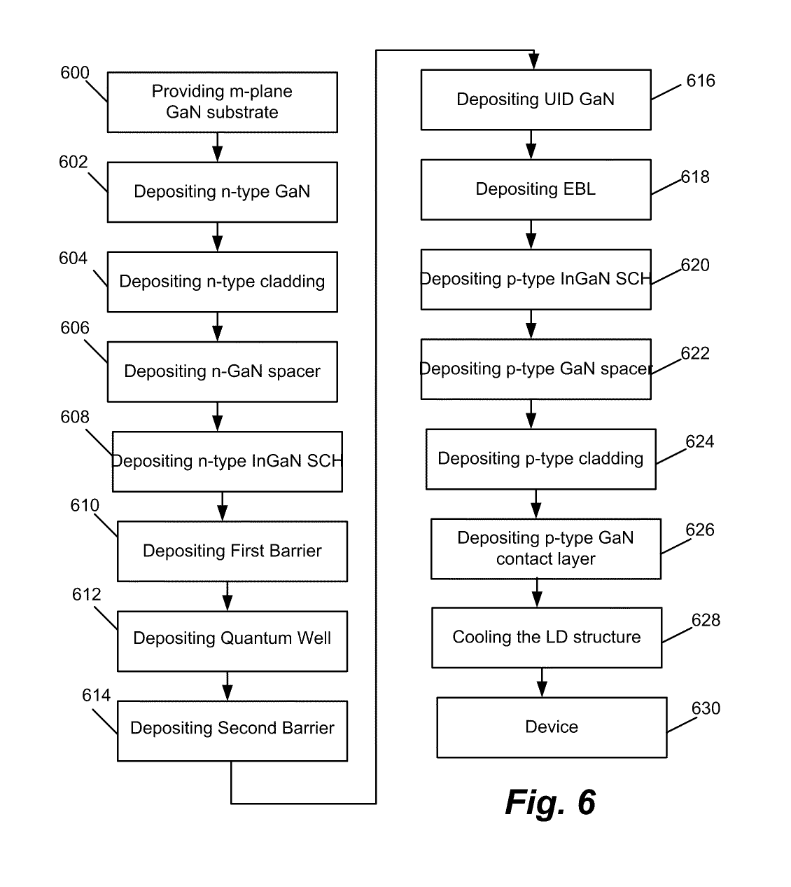

FIG. 6 is a flowchart illustrating a method of fabricating an LD structure, comprising growing one or more III-nitride device layers for a LD on an off-axis surface of an m-plane III-nitride substrate. The method may comprise the following steps.

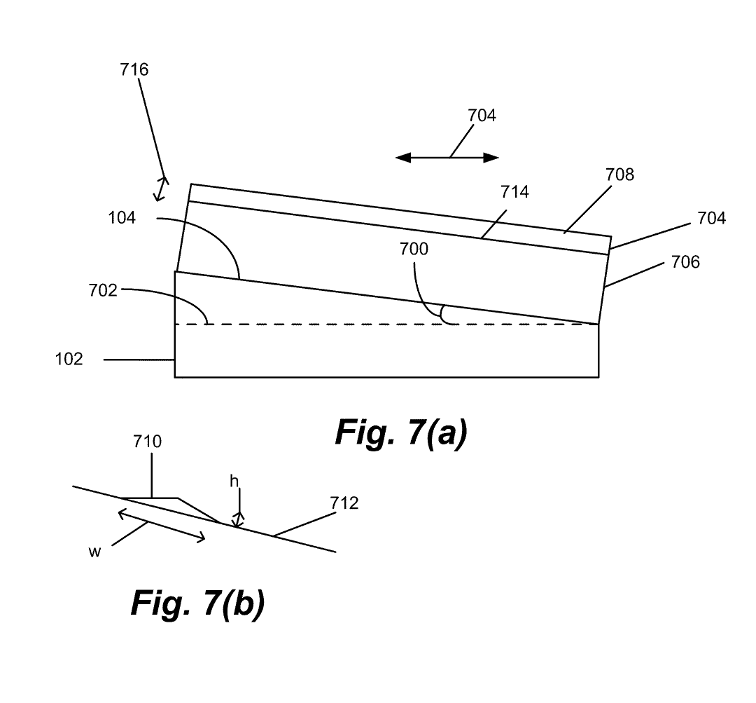

Block 600 represents providing an m-plane GaN substrate having an (e.g., nominally) off-axis surface. The surface may be a miscut, for example. FIG. 7(a) shows a surface 104 that is off-axis by an angle 700 of e.g., nominally +/−1 degree, with respect to the m-plane 702 of the m-plane substrate 102, and towards a c direction 704 of the substrate 102. Both a +1 deg and −1 deg miscut are possible, and other miscut angles different from +/−1 degree are also possible, such as 20-21 and 30-31. (20-21) is miscut m-plane in the true sense. Thus, the surface 104 may be off-axis by more than −1 or +1 degree with respect to an m-plane of the substrate, and towards a c direction of the substrate.

Block 602 represents depositing a III-nitride layer (e.g., n-type GaN layer) epitaxially on the off-axis surface 104.

Block 604 represents depositing an n-type III-nitride cladding layer epitaxially on the n-type layer.

Block 606 represents depositing an n-type GaN spacer layer epitaxially on the n-type cladding layer.

Block 608 represents depositing an n-type InGaN SCH layer epitaxially on the n-type GaN spacer layer, wherein the n-type InGaN SCH layer has an In composition greater than 7%.

Block 610 represents depositing a first quantum well barrier layer epitaxially on the n-type InGaN SCH layer. The depositing may comprise growing the quantum well barriers at a second growth rate slower than the growth rate of the quantum well (in block 612), resulting in smooth surface morphology and interfaces for device layers, including the quantum wells, grown on the quantum well barriers, as compared to the barriers grown at a different faster growth rate, for example.

Block 612 represents depositing an InGaN quantum well layer epitaxially on the first quantum well barrier layer, wherein the InGaN quantum well layer includes at least 20% Indium. The depositing may be growing the quantum well at a first growth rate less than 0.7 Angstroms per second (that may also be greater than 0.3 Angstroms per second), and slower than a growth rate used for other layers in the LD structure. The growing of the quantum wells may be at a first temperature and with an Indium content so that the quantum wells emit green light, wherein the first growth rate maintains smooth interfaces and prevents faceting, as compared to the quantum wells grown at a different growth rate, for example.

Block 614 represents depositing a second quantum well barrier layer epitaxially on the InGaN quantum well layer. The depositing may comprise growing the quantum well barriers at a second growth rate slower than the first growth rate of the quantum well, resulting in smooth surface morphology and interfaces for device layers, including the quantum wells, grown on the quantum well barriers, as compared to the barriers grown at a different faster growth rate, for example.

Blocks 610-614 may be repeated to form a MQW structure comprising a plurality of quantum wells, such that the quantum wells are between quantum well barriers to form a light emitting active region.

Block 616 represents depositing a UID layer on the second barrier layer.

Block 618 represents depositing an EBL epitaxially on the UID layer and active region/layer. The depositing may comprise growing a high (e.g., 2-10%) Aluminum content AlGaN EBL on the active region; and growing subsequent layers (e.g., blocks 620-626) on the active region at a second temperature that is higher than the first temperature (at which the quantum wells are grown) and as compared to without the high Al content AlGaN EBL.

Block 620 represents depositing a p-type InGaN SCH layer epitaxially on the EBL, wherein the p-type InGaN SCH layer has an In composition greater than 7%. In this way, high Indium content InₓGa₁₋ₓN SCH layers (e.g., x>0.07) are on either side of the active region formed in blocks 610-614, and the EBL formed in block 618. The depositing of the InGaN SCH layers of blocks 620 and 608 may comprise growing (1) a third temperature higher temperature than a temperature used to grow other layers in the LD structure, (2) a slower growth rate of less than 0.7 Angstroms per second (that may also be greater than 0.3 Angstroms per second), and (3) a high Trimethylindium/Triethylgallium (TEG) ratio of greater than 1.1, resulting in a smooth and defect free wave-guiding layer.

Block 622 represents depositing a p-type GaN spacer layer epitaxially on the p-type InGaN SCH.

Block 624 represents depositing a p-type III-nitride cladding layer epitaxially on the p-type GaN spacer layer. The n-type and/or p-type cladding of blocks 604 and 624 may comprise AlGaN/GaN asymmetric superlattice on either side of the active region, including alternating AlGaN and GaN layers with an AlGaN layer that is thicker than a GaN layer.

Blocks 620 and 624 may further comprise forming and doping p-waveguide and p-cladding layers, respectively, on one side of the active region, with a magnesium concentration in a range 1×10¹⁸-2×10¹⁹ cm^{˜3}.

Block 626 represents depositing a p-type GaN contact layer epitaxially on the p-type III-nitride cladding layer. The p-GaN contact layer may be deposited on one of the cladding layers (e.g., p-cladding) with a thickness less than 15 nm and with magnesium doping between 7×10¹⁹-3×10²⁰.

Block 628 represents, following the depositing of the p-GaN contact layer, cooling the LD structure down in nitrogen and ammonia ambient, and flowing a small amount of Bis(cyclopentadienyl)magnesium (Cp₂Mg) until a temperature drops below 700 degrees Celsius, thereby forming a Mg—Ga—N layer that has a lower contact resistance to the LD structure.

Block 630 represents the end result of the method, a device such as a III-nitride LD structure comprising one or more III-nitride device layers 704, 706 wherein the III-nitride device layers 704,706 for the LD are grown on an off-axis surface 104 (e.g., but not limited to, a miscut) of an m-plane III-nitride substrate 102 (e.g., but not limited to, a surface 104 that is off-axis by an angle 700 of −1 degree with respect to the m-plane 702 of the substrate 102, and towards a c direction 704 of the substrate 102), as illustrated in FIG. 7(a). The III-nitride device layers 704 may have a top surface 708 with a root mean square (RMS) surface roughness across an area of 25 μm² of 1 nm or less. The top surface 708 may be free of pyramidal hillocks, e.g., free of hillocks 710 having a height h and width was found on the device layer surface 712 (grown on a nominally on-axis m-plane substrate) illustrated in FIG. 7(b). The top surface 708 may be smoother than a top surface 712 of the III-nitride device layer grown on a nominally on-axis m-plane substrate.

FIG. 7 also illustrates a plurality of the device layers 704, 706, wherein (1) the top surface is an interface 714 between two of the device layers 704, 706 grown one on top of another. For example, the interface 714 may be between a quantum well and a quantum well barrier, between a waveguide layer and a cladding layer, or between a waveguide layer and a light emitting active layer. Layers 704 and 706 may also comprise a plurality of device layers.

The top surface 708 or interface 714 may be smoother than the surface shown in FIG. 4(a).

The device layer 704, 706 may be a light emitting active layer including an InGaN quantum well layer having higher In composition, with less In fluctuation across the InGaN quantum well layer, as compared to In composition and In fluctuation in the light emitting InGaN quantum well grown on an on-axis m-plane substrate, and/or as compared to In composition and In fluctuation shown in FIG. 5(a).

The device layer 704, 706 may be a Mg—Ga—N contact layer having a thickness 716 less than 15 nm. A contact resistance to the Mg—Ga—N contact layer may be less than 4E-4 Ohm-cm².

Furthermore, the end result in block 630 may be LD structure 100 as shown in FIG. 1(a) and having one or more of the following (a) a threshold current density of 18kA/cm², when the LD structure is processed into a LD, including facet 180, 182 coating, (b) a top surface that is smoother than the surface shown in FIG. 4(a); (c) the top surface 178 and/or interfaces 154-176 with an RMS surface roughness across an area of 25 μm² of no more than 1 nm and/or free of pyramidal hillocks; (d) an active region (comprising, e.g., InGaN quantum wells 114b) having higher In composition (with less In fluctuation) as compared to In composition and In fluctuation shown in FIG. 5(a)); and (e) a contact resistance to the LD structure of less than 4E-4 Ohm-cm²;

The LD structure may be processed into an LD that emits light having peak intensity at a wavelength that is blue, blue-green light, green light, a wavelength greater than 480 nm (or e.g., in the wavelength range 440-550 nm), or longer than a peak wavelength emitted from a structure on an on-axis m-plane substrate.

The depositing in one or more of blocks 602-626 may comprise growing, e.g., using MOCVD. Furthermore, the growing in one or more of blocks 602-626 may comprise using and almost 100% nitrogen carrier gas at (e.g., nominally) atmospheric pressure resulting in the device layers of blocks 602-626 having smooth surface morphology free of pyramidal hillocks observed in conventional nominally on-axis m-plane GaN substrates. 100% nitrogen carrier gas may represent a nominal value, since between 95% and 100% nitrogen carrier gas may also be used. The device layers grown using 100% nitrogen carrier gas at atmospheric pressure may comprise all of the LD structure's n-type layers, including, for example, a silicon-doped n-type AlGaN/GaN superlattice, resulting in smooth interfaces and excellent structural properties for the LD structure, as compared to device layers grown without using 100% nitrogen carrier gas.

Possible Modifications

1. This invention can be applied to polar, nonpolar and semipolar LDs. The present invention includes increased ranges of miscuts or off-axis (not limited to within +/−1 deg, but also above that range) that can no longer be treated as nonpolar, and hence the term semipolar would make more sense. The present invention covers new semipolar planes like (20-21) and (30-31), for example.

2. This invention can be applied for any wavelength ranging from Ultraviolet (UV) to green spectral range light emission (and possibly longer wavelengths).

3. This invention can be applied to LD structures containing InGaN, GaN or AlInGaN waveguiding layers.

4. This invention can be applied to LD structures containing InGaN, GaN or AlInGaN barriers in the active region.

5. This invention can be applied to LD structures containing InGaN, GaN or AlInGaN barriers in the active region where a part of the barrier is grown at a higher temperature compared to the well.

6. The lower cladding layer can be a quaternary alloy (AlInGaN) instead of ternary AlGaN based alloys.

7. The asymmetric design could also suggest a difference in AlGaN composition for the lower and upper cladding. A GaN cladding instead of AlGaN cladding could be used for example.

8. The asymmetric design could also include a structure with different InGaN composition for the lower and upper waveguide layers.

9. This invention can be applied to LD structures on nonpolar and semipolar substrates for all miscut angles.

10. The described growth rates and temperatures are for MOCVD. Other growth methods such as MBE may also be possible. Other growth rates, e.g. for the SCH and quantum well are also possible. For example, both <0.3 Å/s and >0.7 Å/s are possible. The growth is typically, but not limited to, as close to atmospheric pressure as possible.

11. Facet coating may include DBR coating, which used two materials with different refractive indices. In the present invention, SiO₂ and Ta₂O₅ were used for facet coating. Other materials are possible.

12. A particular ridge waveguide does not have to be used. The ridge widths in the present invention are in a range of 2 to 10 μm, but are not limited to this range.

13. Layers such as the spacer layers, AlGaN cladding, etc., are optional and may be omitted as desired. Other layers may be added.

Advantages and Improvements

This invention has the following advantages compared to conventional m-plane GaN based LD structures:

1. The use of miscut substrates, along with the growth of n-type layers in nitrogen carrier gas, resulted in a pyramidal hillock-free and smooth surface morphology, and smoother interfaces.

2. The use of slower growth rates for wells and barriers resulted in smooth quantum well interfaces and reduced In fluctuation in the well, thereby resulting in improved stability of the InGaN wells, that allowed growth of p-type layers at higher temperature than if faster well and barrier growth rates were used. The p-GaN layer may be grown at a temperature Tg ˜900-1000° C., for example.

3. Use of a high Al content (e.g., more than 15%) AlGaN EBL allowed higher growth temperature for layers above the active region (e.g., p-GaN growth temperature Tg ˜900-1000° C.).

4. The use of asymmetric AlGaN SPSLS allowed growth of p-AlGaN layers with higher average Al composition (e.g., more than 5% Al).

5. The novel contact scheme reduced the contact resistance significantly.

6. All the above changes resulted in a LD with much lower threshold current density (e.g., 18 kA/cm²) and longer stimulated emission wavelength (e.g., 492 nm), compared to a conventional LD structure.

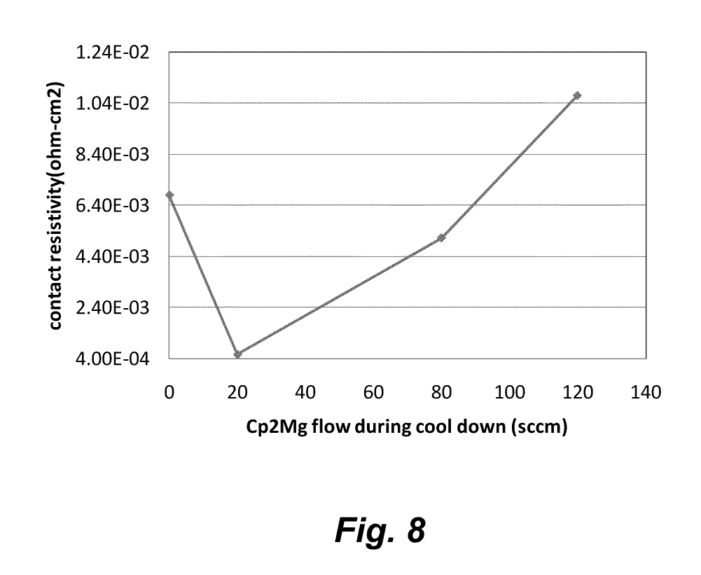

From atomic force microscope (AFM) measurement, the root mean square (RMS) surface roughness across 25 μm² was less than 1 nm and from Transmission Line Measurement (TLM), the contact resistance was 4E-4 Ohm-cm², as shown in FIG. 8.

Further information on the present invention can be found in [20-24].

### REFERENCES

The following references are incorporated by reference herein:
[1] S. Nakamura, M. Senoh, S. Nagahama, N. Iwasa, T. Yamada, T. Matsushita, H. Kiyoku, and Y. Sugimoto, Jpn. J. Appl. Phys. 35, L74 (1996).
[2] M. C. Schmidt, K-C Kim, R. M. Farrell, D. F. Feezell, D. A. Cohen, M. Saito, K. Fujito, J. S. Speck, S. P. DenBaars, and S. Nakamura, Jpn. J. Appl. Phys. 46, L190 (2007).
[3] K. Okamoto, H. Ohta, S. F. Chichibu, J. Ichihara, and H. Takasu, Jpn. J. Appl. Phys. 46, L187 (2007).
[4] J. S. Speck and S. F. Chichibu, MRS Bulletin 34, 304 (2009).
[5] S. H. Park, D. Ahn, Appl. Phys. Lett. 90,013505 (2007).
[6] S. H. Park, D. Ahn, IEEE J. Quantum Electron. 43, 1175 (2007).
[7] Kubota et al., Applied Physics Express 1 (2008) 011102.
[8] K. Okamoto, T. Tanaka, and M. Kubota, Appl. Phys. Express 1, 072201 (2008).
[9] Tsuda et al., Applied Physics Express 1 (2008) 011104.
[10] H. Ohta and K. Okamoto, MRS Bulletin 34, 324 (2009).
[11] T. Miyoshi, T. Yanamoto, T. Kozaki, S. Nagahama, Y. Narukawa, M. Sano, T. Yamada, and T. Mukai, Proc. SPIE 6894, 689414 (2008).
[12] D. Queren, A. Avramescu, G. Briiderl, A. Breidenassel, M. Schillgalies, S. Lutgen, and U. StrauB, Appl. Phys. Lett. 94, 081119 (2009).
[13] Feezell et al., Japanese Journal of Applied Physics, Vol. 46, No. 13, 2007, pp. L284-L286.
[14] K. Okamoto, T. Tanaka, M. Kubota, and H. Ohta, Jpn. J. Appl. Phys. 46, L820 (2007).
[15] K. M. Kelchner, Y. D. Lin, M. T. Hardy, C. Y. Huang, P. S. Hsu, R. M. Farrell1, D. A. Haeger, H. C. Kuo, F. Wu, K. Fujito, D. A. Cohen, A. Chakraborty, H. Ohta, J. S. Speck, S. Nakamura, and S. P. DenBaars, Appl. Phys. Express (2009) (in press).
[16] A. Hirai, Z. Jia, M. C. Schmidt, R. M. Farrell, S. P. DenBaars, S. Nakamura, and J. S. Speck, Appl. Phys. Lett. 91, 191906 (2007)
[17] “Effect of Substrate Misorientation on the Structural and Optical Properties of m-plane InGaN/GaN Light Emitting Diodes,” R. M. Farrell, D. A. Haeger, X. Chen, M. Iza, A. Hirai, K. M. Kelchner, K. Fujito, A. Chakraborty, S. Keller, H. Ohta, S. P. DenBaars, J. S. Speck, and S. Nakamura (manuscript under review).
[18] H. Yamada, K. Iso, M. Saito, K. Fujito, S. P. DenBaars, S. Speck, and S. Nakamura, Jpn. J. Appl. Phys. 46, L1117 (2007).
[19] Farrell et al., Japanese Journal of Applied Physics, Vol. 46, No. 32, 2007, pp. L761-L763.
[20] Po Shan Hsu, Kathryn M. Kelchner, Anurag Tyagi, Robert M. Farrell, Daniel A. Haeger, Kenji Fujito, Hiroaki Ohta, Steven P. DenBaars, James S. Speck, and Shuji Nakamura, “InGaN/GaN Blue Laser Diode Grown on Semipolar (30-31) Free-Standing GaN Substrates,” Applied Physics Express 3 (2010) 052702.
[21] You-Da Lin, Matthew T. Hardy, Po Shan Hsu, Kathryn M. Kelchner, Robert M. Farrell, Arpan Chakraborty, Hiroaki Ohta, James S. Speck, Steven P. DenBaars, and Shuji Nakamura, entitled “Blue-Green InGaN/GaN Laser Diodes on Miscut m-plane GaN Substrate,” Applied Physics Express 2 (2009) 082102.
[22] Presentation Slides given by Shuji Nakamura at the 2009 Annual Review for Solid State Lighting and Energy Center (SSLEC), University of California, Santa Barbara (November 2009).
[23] Presentation Slides given by Youda Lin at the 2009 Annual Review for SSLEC, University of California, Santa Barbara (November 2009).
[24] Presentation Slides given by Kate Kelchner at the 2009 Annual Review for SSLEC, University of California, Santa Barbara.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method of fabricating a III-nitride laser diode (LD) structure, comprising:
growing one or more III-nitride device layers for a LD on an off-axis surface of a nonpolar or semipolar III-nitride substrate.

2. The method of claim 1, wherein the surface is off-axis by −1 or +1 degree with respect to an m-plane of the substrate, and towards a c direction of the substrate.

3. The method of claim 1, wherein the surface is off-axis by more than −1 or +1 degree with respect to an m-plane of the substrate, and towards a c direction of the substrate.

4. The method of claim 2, further comprising using 100% nitrogen carrier gas at atmospheric pressure to grow the one or more device layers on the off-axis surface of the substrate, resulting in the device layers having smooth surface morphology free of pyramidal hillocks observed in device layers grown on nominally on-axis m-plane GaN substrates.

5. The method of claim 1, wherein the device layers comprise all of the LD structure's n-type layers.

6. The method of claim 5, wherein the n-type layers further comprise a silicon-doped n-type AlGaN/GaN superlattice, resulting in smooth interfaces and excellent structural properties for the LD structure, as compared to device layers grown without using 100% nitrogen carrier gas.

7. The method of claim 1, wherein growing the device layers further comprises growing one or more quantum wells at a first growth rate of more than 0.3 Angstroms per second and less than 0.7 Angstroms per second, and slower than a growth rate used for other layers in the LD structure.

8. The method of claim 7, further comprising growing the quantum wells at a first temperature and with an Indium content so that the quantum wells emit green light, wherein the first growth rate maintains smooth interfaces and prevents faceting as compared to the quantum wells grown at a different growth rate.

9. The method of claim 8, wherein each of the quantum wells are between quantum well barriers to form a light emitting active region, and further comprising:
growing the quantum well barriers at a second growth rate slower than the first growth rate, resulting in smooth surface morphology and interfaces for the device layers, including the quantum wells, grown on the quantum well barriers, as compared to the barriers grown at a different faster growth rate.

10. The method of claim 9, further comprising:
growing a high Aluminum content AlGaN electron blocking layer on the active region; and
growing subsequent layers on the active region at a second temperature that is higher than the first temperature and as compared to without the high Al content AlGaN electron blocking layer.

11. The method of claim 10, wherein high Indium content InₓGa₁₋ₓN separate confinement heterostructure (SCH) layers are on either side of the active region and the electron blocking layer, with x>7%, and further comprising growing the SCH layers at:
(1) a third temperature higher temperature than a temperature used to grow other layers in the LD structure,
(2) a slower growth rate of more than 0.3 Angstroms per second and less than 0.7 Angstroms per second, and
(3) a high Trimethylindium/Triethylgallium (TEG) ratio of greater than 1.1, resulting in a smooth and defect free wave-guiding layer.

12. The method of claim 9, further comprising forming an AlGaN/GaN asymmetric superlattice as cladding layers, on either side of the active region, including alternating AlGaN and GaN layers with the AlGaN layer that is thicker than the GaN layer.

13. The method of claim 9, further comprising forming and doping p-waveguide and p-cladding layers, on one side of the active region, with a magnesium concentration in a range 1×10¹⁸-2×10¹⁹ cm⁻³.

14. The method of claim 13, further comprising depositing a p-GaN contact layer on a p-cladding layer, with a thickness less than 15 nm and a magnesium doping between 7×10¹⁹-3×10²⁰.

15. The method of claim 14, further comprising:
following the depositing of the p-GaN contact layer, cooling the LD structure down in nitrogen and ammonia ambient, and flowing a small amount of Bis(cyclopentadienyl)magnesium (Cp₂Mg) until a temperature drops below 700 degrees Celsius, thereby forming a Mg—Ga—N layer that has a lower contact resistance to the LD structure.

16. A III-nitride device layer in a III-nitride based laser diode (LD) structure, comprising:
(a) a III-nitride device layer for a LD grown on an off-axis surface of an m-plane III-nitride substrate.

17. The device layers of claim 16, wherein the III-nitride device layer has a top surface with a root mean square (RMS) surface roughness across an area of 25 μm² of 1 nm or less.

18. The device layers of claim 16, wherein the top surface is free of pyramidal hillocks.

19. The device layer of claim 18, wherein the top surface is smoother than a top surface of the III-nitride device layer grown on a nominally on-axis m-plane substrate.

20. The device layer of claim 16, wherein the III-nitride device layer is grown on the surface that is off-axis by −1 or +1 degree with respect to the m-plane of the substrate, and towards c direction of the substrate.

21. The device layer of claim 16, further comprising a plurality of the device layers, wherein:
(1) the top surface is an interface between two of the device layers grown one on top of another; and
(2) the interface is between one or more of the following: a quantum well and a quantum well barrier, between a waveguide layer and a cladding layer, or between a waveguide layer and a light emitting active layer.

22. The device layer of claim 16, wherein the device layers are in the LD structure processed into the LD, such that, with facet coating, the LD has a threshold current density of 18 kA/cm² or less.

23. The device layer of claim 16, wherein the top surface is smoother than the surface shown in FIG. 4(a).

24. The device layer of claim 16, wherein the device layer is a light emitting active layer including an InGaN quantum well layer having higher In composition, with less In fluctuation across the InGaN quantum well layer, as compared to In composition and In fluctuation in the light emitting InGaN quantum well grown on an on-axis m-plane substrate.

25. The device layer of claim 16, wherein the device layer is a light emitting active layer including an InGaN quantum well layer, having higher In composition, with less In fluctuation across the InGaN quantum well layer, as compared to In composition and In fluctuation shown in FIG. 5(a)).

26. The device layer of claim 16, wherein the device layer is an Mg—Ga—N contact layer having a thickness less than 15 nm.

27. The device layer of claim 25, wherein a contact resistance to the Mg—Ga—N contact layer is less than 4E-4 Ohm-cm².

28. The device layer of claim 16, wherein, when the LD structure is processed into an LD, the LD emits light having peak intensity at a wavelength corresponding to at least blue-green or green light.
